(19) United States
(12) Patent Application Publication
(10) Pub. No.: US 2026/0297731 A1
(43) Pub. Date: Oct. 1, 2026

(54) METHODS OF MAKING CARBON COATED PARTICLES FROM RECLAIMED CARBON AND OTHER PARTICLES

(71) Applicant: Cabot Corporation, Boston, MA (US)

(72) Inventors: David M. Matheu, Arlington, MA (US); Frederick H. Rumpf, Billerica, MA (US); Theis F. Clarke, Houston, TX (US)

(21) Appl. No.: 19/477,259

(22) PCT Filed: Apr. 25, 2024
(86) PCT No.: PCT/US2024/026188

§ 371 Date: Oct. 21, 2025

Related U.S. Application Data
(60) Provisional application No. 63/462,869, filed on Apr. 28, 2023.

(51) Int. Cl. C23C 16/26; C01B 3/28; C01B 33/149; C09C 1/56

(52) U.S. Cl. CPC C23C 16/26; C01B 3/28; C01B 33/149; C09C 1/56; C01B 2203/0272; C01B 2203/06; C01B 2203/1235; C01P 2004/84

(57) ABSTRACT

Methods to form carbon coated particles are described. Methods to form coated particles involve subjecting the particles to an energy source that is at least one of hot gas, microwave energy, induction energy, direct current passing through the particles, electromagnetic radiation, or solar radiation, so as to form heated particles, and feeding a hydrocarbon source that is in the form of a gas or vapor into the chamber, such that the hydrocarbon source pyrolyzes, in at least in part, in the chamber to form carbon deposits, and thereby coating the heated base particles with the carbon deposits and form the carbon coated particles. Coated particles produced by one of the methods of the present invention is further described. The advantages achieved with the methods are further described.

The present invention relates to methods for coating various particles with a carbon coating, such as the carbon coating of reclaimed carbon and other carbon particles and other types of particles. The present invention further relates to carbon-coated carbon particles and other carbon-coated particles, as well as articles containing the same.

There is more and more demand and effort in the recycling of materials so as to avoid the materials being disposed of in waste fills and to avoid further depletion of natural resources.

Thus, the use of reclaimed carbon (rC) from used tires (or other sources) as a substitute for carbon black (CB) in rubber reinforcement applications may be a promising strategy. However, reclaimed carbon suffers from low rubber reinforcement, such as low tensile modulus, low tear strength, and/or low fatigue life, compared with CB with the same surface area and structure as measured by OAN. One hypothesis was that a main cause for low rubber reinforcement of rC was its low surface activity. Other possible causes of low rubber reinforcement include a high percentage of large and hard-to-disperse reclaimed particle aggregates present in rubber as defects in the form of large undispersed particles, which would significantly reduce tensile strength, tear strength, and fatigue life of rubber. Yet, another possible cause of the low reinforcement of the reclaimed carbon is its compact structure, which is very different from the more extensive fractal structure of carbon black that enables high rubber reinforcement. Beside reclaimed carbon, other materials from recycling or other materials can have the same or similar problems as reclaimed carbon.

Accordingly, there is a need in the industry to develop processes that can take rC and other similar particles that are not suitable as-is for use as filler in rubber reinforcement applications and other applications so as to make them a suitable replacement or suitable partial replacement for virgin carbon black. For example, coating reclaimed carbon particles with a fresh carbon-black like carbon surface is expected to enhance its surface activity. While some techniques may have been attempted to coat particles with carbon, there is demand in the industry to provide alternative methods of coating such particles as rC, that do not rely on carbon black reactors or similar techniques.

All of the patents and publications mentioned throughout are incorporated in their entirety by reference herein.

### SUMMARY OF THE PRESENT INVENTION

A feature of the present invention is to provide methods to coat reclaimed carbon with a carbon layer.

An additional feature of the present invention is to provide methods to coat particles, other than reclaimed carbon, with a carbon layer, such as particles that are non-ASTM reinforcement grade particles.

A further feature of the present invention is to provide methods to make reclaimed carbon a more viable material for use as reinforcement grade material in such applications as rubber.

A still further feature of the present invention is to provide methods to alter one or more properties in reclaimed carbon or other particles so as to make it a more viable material for use as a reinforcement grade filler.

Also, a feature of the present invention is to provide methods to process reclaimed carbon and/or other carbon particles and/or other non-ASTM reinforcement grade particles and non-carbon containing particles, so that the particles can impart comparable rubber reinforcement properties, such as, but not limited to, acceptable tensile modulus, hysteresis (as measured by tan delta), tear strength, and/or fatigue life compared to virgin carbon black.

A further feature of the present invention is to provide methods to process reclaimed carbon and/or other carbon particles and/or other non-ASTM reinforcement grade particles and non-carbon containing particles, so that the particles can impart superior rubber reinforcement properties, such as, but not limited to, acceptable tensile modulus, hysteresis (as measured by tan delta), tear strength, and/or fatigue life compared to the unprocessed starting material.

An additional feature of the present invention is to provide carbon-coated reclaimed carbon and/or carbon-coated particles with one or more different properties compared to non-carbon coated reclaimed carbon (e.g., reclaimed carbon or milled reclaimed carbon).

An additional feature of the present invention is to provide methods to make carbon-coated reclaimed carbon and/or carbon-coated particles with reduced or no generation of carbon dioxide emissions.

An additional feature of the present invention is to provide methods to make carbon-coated reclaimed carbon and/or carbon-coated particles having low greenhouse gas intensity and/or high amounts of recycled content.

To achieve these and other advantages, and in accordance with the purposes of the present invention, as embodied and broadly described herein, the present invention, in part, relates to methods for forming carbon coated base particles, for example, carbon coated carbon particles. More particularly, one method relates to methods to form carbon coated base particles, where the method includes introducing base particles into a chamber and subjecting the base particles to an energy source that is at least one of hot gas, microwave energy, induction energy, direct current passing through said base particles, electromagnetic radiation, or solar radiation, so as to form heated base particles. The method includes feeding a hydrocarbon source that includes or is a gas or vapor into the chamber. The hydrocarbon source pyrolyzes, at least in part, in the chamber to form carbon deposits, and thereby coating the heated base particles with the carbon deposits and form the carbon coated base particles. Exemplary base particles that are utilized in the method can be or include reclaimed carbon particles or other carbon particles that are non-ASTM reinforcement grade particles.

The present invention also relates to utilizing the above process with particles that, for instance, have lower amounts of carbon in the particle as compared to reclaimed carbon.

The present invention, furthermore, in part, relates to a method to form carbon coated precipitated silica particles. The method can include introducing precipitated silica particles into a chamber and subjecting the precipitated silica particles to microwave energy or other forms of energy as detailed herein, to form heated precipitated silica particles. The method further includes feeding a hydrocarbon source that includes or is a gas or vapor into the chamber. The hydrocarbon source pyrolyzes, in at least in part, in the chamber to form carbon deposits, and thereby coating the heated precipitated silica particles with the carbon deposits and form the carbon coated precipitated silica particles.

Further, the present invention, in part, relates to carbon coated particles and carbon coated particles formed by methods of the present invention.

The present invention further relates to products and/or articles, such as but not limited to, tires, parts of tires, and/or elastomer composites formed at least in part from the coated particles of the present invention.

It is to be understood that both the foregoing general description and the following detailed description are exemplary and explanatory only and are intended to provide a further explanation of the present invention as claimed.

The accompanying drawings, which are incorporated in and constitute a part of this application, illustrate various features of the present invention and, together with the description, serve to explain the principles of the present invention.

### BRIEF DESCRIPTION OF DRAWINGS

FIG. 1 is a cross sectional simplified view of an example of a system with a chamber suitable for use in a method of the present invention.

FIG. 2 is a cross sectional simplified view of a further example of a two-chamber system suitable for use in a method of the present invention.

The Figures are not to scale and are provided as simplified views and do not necessarily show all possible embodiments or components that can be present.

### DETAILED DESCRIPTION OF THE PRESENT INVENTION

The present invention relates to methods to carbon-coat various types of particles, carbon coated particles obtained thereby, and the concomitant production of hydrogen. The particles that are coated can be carbon particles. The particles that are coated can be particles that have a carbon content. The particles that are coated can be non-ASTM reinforcement grade particles. The carbon particles that can be coated include reclaimed carbon. The particles that are coated can be non-carbon containing particles such as silica particles, preferably precipitated silica particles.

A method of the present invention relates to forming carbon-coated base particles. This method includes, comprises, consists essentially of, or consists of introducing base particles into a chamber and subjecting the base particles to an energy source that is at least one of microwave energy, induction energy, direct current passing through said base particles, electromagnetic radiation, or solar radiation, so as to form heated base particles. The method includes feeding a hydrocarbon source that includes, comprises, consists essentially of, consists of, or is a gas or vapor into the chamber. The hydrocarbon source pyrolyzes, at least in part, in the chamber to form carbon deposits, thereby coating the heated base particles with the carbon deposits to form the carbon coated base particles. The base particles can comprise, consists essentially of, consists of, include or are a) reclaimed carbon particles and/or b) other carbon particles that are non-ASTM reinforcement grade particles. The temperature of the heated base particles may be at least 800° C., at least 900° C., at least 1000° C., at least 1100° C., at least 1200° C., at least 1300° C., at least 1400° C., or at least 1500° C., for example from 900 to 1200° C. or from 1300 to 1600° C.

The base particles that are introduced into a chamber can be various types of carbon particles. Further, as described later, in lieu of carbon particles, the particles can be particles that do or do not contain carbon. For purposes of the present invention, a carbon particle is a particle that consist primarily of carbon. The carbon particle generally has carbon as the primary component (e.g., carbon is present in at least 75%, at least 80%, at least 85%, at least 90%, at least 95%, at least 98%, at least 99%, for example, from 75% to 95% or from 75% to 100% by weight based on the total weight of the particle). Examples of the carbon particles include, but are not limited to, reclaimed carbon particles (rC). The rC can optionally be deaggregated (i.e., deaggregated reclaimed carbon or deaggregated rC that is deaggregated from reclaimed carbon aggregates (i.e., reclaimed aggregates)).

rC, such as rC aggregates, are commercially available. Generally, the rC aggregates result from the pyrolysis of tires and/or other rubber or plastic materials that contained filler materials or reinforcement materials, such as carbon black. The rC is made primarily of carbon black that was used to reinforce rubber or plastic. The source tire and other rubber or other source material contains components that can pyrolyze, such as the rubber components, and due to the high temperatures described herein for methods of the present invention, at least a portion of these components are pyrolyzed to produce pyrolysis carbon. The pyrolysis carbon is processed to remove at least one macroscopic contaminant such as fabric or wire and produce reclaimed carbon (rC). The rC can be optionally milled to reduce the average particle size by jet milling or as described in WO2023122582, the entire contents of which are incorporated by reference.

Carbon particles that are non-ASTM reinforcement grade particles are carbon particles that would not satisfy one of the ASTM 100, 200, or 300 series carbon black fillers, or would not satisfy one of the ASTM 500, 600, or 700 series carbon black fillers. Examples of such a carbon particle may be carbon black but also include and are not limited to solid hydrothermal carbon (HTC), silicon-treated carbon black, silica coated carbon black, graphene, reduced graphene oxide, single walled carbon nanotubes, multi walled carbon nanotubes, carbon nanostructures, carbon black coated particles, and biochar. Further the reclaimed carbon particles referred to above would also not satisfy this ASTM standard.

In lieu of carbon particles, other types of particles that have some carbon content (e.g., from 10% to 75 wt % or from 10 wt % to 60 wt % or from 10 wt % to 50 wt % or from 10 wt % to 40 wt carbon based on total weight of the particle) can be used. For instance, the particles can be graphene oxide, lignin, or nanocrystalline cellulose. Other examples of carbon containing particles include bio-based particles. Specific examples of bio-based particles include, but are not limited to, polysaccharides or engineered polysaccharides.

In lieu of carbon particles, particles that have little or no carbon content (e.g., less than 10 wt % carbon). For example, the particles can be precipitated silica, rice husk silica, clays, nanoclays, diatomaceous earth, metal oxides or metal carbonates.

As an option, and to assist in more effective heating of the base particles and further result in possible a more uniform or more efficient coating of the base particles, the base particles can have one or more of the following particle size parameters:
A: Volume weighted mean aggregate size of below 2 microns (e.g., below 1.75 microns, below 1.5 microns, below 1 micron, below 0.9 micron, below 0.8 micron, below 0.7 micron, below 0.6 micron, such as from 0.5 micron to 1.9 microns, from 0.5 micron to 1.7 microns, from 0.5 micron to 1.5 microns, from 0.5 micron to 1.25 microns, from 0.5 micron to 1 micron, from 0.5 micron to 0.8 micron, from 0.6 micron to 1.9 microns, from 0.7 micron to 1.9 microns, from 0.8 micron to 1.9 microns, from 0.9 micron to 1.9 microns, from 1 micron to 1.9 microns);
B: D10 aggregate size of below 400 nm (e.g., below 375 nm, below 350 nm, below 325 nm, below 300 nm, below 275 nm, below 250 nm, below 225 nm, below 200 nm, below 175 nm, below 150 nm, such as from 140 nm to 390 nm, from 150 nm to 390 nm, from 160 nm to 390 nm, from 170 nm to 390 nm, from 180 nm to 390 nm, from 190 nm to 390 nm, from 200 nm to 390 nm, from 140 nm to 380 nm, from 140 nm to 350 nm, from 140 nm to 300 nm, from 140 nm to 250 nm, from 140 nm to 200 nm);
C: D25 aggregate size of below 1 micron (e.g., below 0.9 micron, below 0.8 micron, below 0.7 micron, below 0.6 micron, below 0.5 micron, below 0.4 micron, below 0.3 micron, below 0.25 micron below 0.2 micron, such as from 0.2 micron to 0.9 micron, from 0.3 micron to 0.9 micron, from 0.4 micron to 0.9 micron, from 0.5 micron to 0.9 micron, from 0.2 micron to 0.8 micron, from 0.2 micron to 0.5 micron, from 0.2 micron to 0.4 micron);
D: D50 aggregate size of below 4 microns (e.g., below 3.5 microns, below 3 microns, below 2.5 microns, below 2 microns, below 1.5 microns, below 1 micron, below 0.75 micron, below 0.5 micron, below 0.4 micron, below 0.35 micron, such as from 0.35 micron to 3.9 microns, from 0.4 micron to 3.9 microns, from 0.5 micron to 3.9 microns, from 0.6 micron to 3.9 microns, from 0.7 micron to 3.9 microns, from 0.8 micron to 3.9 microns, from 0.35 micron to 3.5 microns, from 0.35 micron to 3 microns, from 0.35 micron to 2.5 microns, from 0.35 micron to 2 microns, from 0.35 micron to 1.5 microns, from 0.35 micron to 1 micron, from 0.35 to 0.9 micron);
E: D75 aggregate size of below 4.5 microns (e.g., below 4 microns, below 3.5 microns, below 3 microns, below 2.75 microns, below 2.5 microns, below 2.25 microns, below 2 microns, below 1.75 microns, below 1.5 microns, below 1.25 microns, below 1 micron, such as from 1 micron to 4 microns, from 1 micron to 3.5 microns, from 1 micron to 3 microns, from 1 micron to 2.5 microns, from 1 micron to 2 microns, from 1 micron to 1.5 microns, from 1.1 microns to 4 microns, from 1.2 microns to 3.5 microns, from 1.3 microns to 3 microns);
F: D90 aggregate size of below 5 microns (e.g., below 4.5 microns, below 4 microns, below 3.5 microns, below 3 microns, below 2.75 microns, below 2.5 microns, below 2.25 microns, below 2 microns, such as from 2 microns to 4.5 microns, from 2 microns to 4.25 microns, from 2 microns to 4 microns, from 2 microns to 3.5 microns, from 2 microns to 3 microns, from 2.25 microns to 4 microns, from 2.5 microns to 4 microns, from 2.75 microns to 4 microns);
G: Heterogeneity Index (H.I.) (defined as the ratio of volume weighted mean aggregate size to number weighted mean aggregate size) of below 20 (e.g., below 15, below 10, below 9, below 8, below 7, below 6, below 5, below 4, such as from 4 to 15, from 4 to 10, from 4 to 9, from 4 to 7, from 4 to 6, from 5 to 15, from 6 to 15, from 7 to 15, from 8 to 12);
H: Mass %>1 micron of below 60% (e.g., below 55%, below 50%, below 45%, below 40%, below 40%, below 35%, below 30%, below 25%, below 20%, below 15%, below 10%, such as from 10% to 55%, from 10% to 50%, from 10% to 45%, from 10% to 40%, from 10% to 35%, from 10% to 30%, from 10% to 25%, from 15% to 45%, from 20% to 45%, from 25% to 45%, from 30% to 45%).

The base particles can have one or all of the above aggregate size parameters. Any combination of A through H is possible (e.g., one or more of A-H, two or more of A-H, three or more of A-H, four or more of A-H, five or more of A-H, six or more of A-H, seven or all of A-H).

A deaggregated rC compared to rC aggregates can have any one or more of the mean aggregate size, D10 aggregate size, D25 aggregate size, D50 aggregate size, D75 aggregate size, D90 aggregate size, H.I., and/or mass %>1 micron, reduced by 10%, reduced by 20%, reduced by 50%, reduced by 75% or more.

The rC can contain amounts of non-carbon material. For instance, the rC can contain from 1 wt % to 20 wt % or more (by total weight of the rC) of non-carbon material or components, such as, but not limited to, silica particles and/or ZnO and the like.

Regarding the chamber, the chamber can have any suitable shape and size and be constructed of material so as to permit energy from an energy source to contact the base particles to result in heated base particles and have the hydrocarbon source pyrolyze. For instance, the chamber can be a fluidized bed reactor, an ablative pyrolysis reactor, a vacuum pyrolysis reactor, a fixed bed drop-type reactor, or a solar pyrolyzer.

Regarding the energy sources that the base particles are subjected to so as to result in heated base particles, these energy sources include, but are not limited to, exposure to hot gas, resistive heating, microwave energy, induction energy, direct current passing through the base particles, electromagnetic radiation, or solar radiation. The heating of the particles can be by way of dielectric heating or induction heating. For methods relying on passing an electrical current through the base particles, it is preferable that the base particle exhibit electrical conductivity.

The microwave energy can be obtained from any type of microwave generator. For example, the microwave generator can be a magnetron that includes a vacuum sealed chamber with a heated filament and magnetic field. When the filament is heated, it emits electrons that are accelerated by the magnetic field, creating a stream of electrons that move towards an anode. As the electrons pass through a resonant cavity, the electrons oscillate and produce a high-frequency electromagnetic field, which is then directed out of the cavity by an antenna. Other types of microwave generators include klystrons, traveling-wave tubes, solid-state devices, and the like. The microwave generator can be located within the chamber or adjacent to the chamber. Commercial examples include, but are not limited to, MUEGGE microwave generators, CEM microwaves, such as the CEM LABWAVE and AIRWAVE models, THERMEX THERMATRON microwave generators, and the like.

The microwave generator can produce electromagnetic radiation with frequencies of at least 0.5 GHz, such as from 0.5 GHz to 300 GHz or higher.

The microwave generator can operate at power levels ranging from 300 watts to 4 MW or higher, such as from 1 kW to 1 MW, from 10 kW to 500 kW, from 100 kW to 400 kW, or from 200 kW to 300 kW.

The induction energy can be provided by an induction heater. Induction heating is a non-contact method of heating a material by utilizing a strong magnetic field that induces an alternating current in the material, which excites the atoms in the material and heats it up. Induction heaters incorporate a coil directly fed from an electricity supply. Also known as the inductor, the coil is used to transfer the energy from a power unit to the material. Inductors range in complexity from a simple wound solenoid including of a number of turns of copper tube wound around a mandrel, to a precision item machined from solid copper, brazed and soldered together. Commercial examples of such induction heaters include, but are not limited to, EASYHEAT and EKOHEAT induction heating systems by AMBRELL, INDUCTOFORGE induction heating systems by INDUCTOHEAT, HEATLINE induction heaters by ENRX, and the like.

The induction heater, for instance, can be operated at a frequency of at least 5 kHz, such as from 5 kHz to 500 kHz or higher. The induction heater can operate at an induction heater energy level of at least 50 MJ/kg, such as from 50 MJ/kg to 250 MJ/kg or higher (where kg is the amount of particles being processed in the chamber).

Direct current can be passed through the base particles by a direct current power source to heat the base particles. The direct current power source can be batteries, power supplies, electrochemical cells, renewable power systems, and the like.

The direct current power source, for instance, can have a voltage of at least 1V to 400V or higher. For example, the voltage of the direct current power source can be from 10V to 300V, 50V to 200V, or 100V to 150V.

Electromagnetic radiation includes waves of the electromagnetic field, such as radio waves, infrared, microwaves, visible light, ultraviolet, X-rays, induction heating, and gamma rays. Examples of microwave generators and induction heating generators are provided above. Other devices that generate electromagnetic radiation include infrared heaters, lasers, radio frequency heaters, and the like.

The frequency and power necessary for electromagnetic radiation generators depend on the type of electromagnetic radiation being generated. For example, the frequency range of infrared heaters can be between 1 μm and 100 μm, and the power levels can range from 1 W to 100 kW. The frequency range of radio frequency heaters can be between 1 kHz and 100 MHz, and the power levels can range from 1 W to 100 kW. The frequency of laser systems can be from 1 tHz to 100 tHz and the power levels can range from 1 mW to 100 kW.

Solar radiation can be used to heat the particles such as the base particles. The present invention can utilize solar radiation concentrators that increase the intensity of solar radiation to heat the base particles. Solar radiation concentrators can include solar thermal collectors, solar furnaces, solar ovens, solar kilns, and the like. These devices utilize parabolic troughs, dish collections, tower collectors, mirrors, lenses, reflectors, and the like to magnify and concentrate the heat of solar radiation onto the base particles.

The energy source utilized can optionally be produced from renewable energy production, such as renewable electricity (e.g., solar generated, wind generated, and the like).

With respect to the hydrocarbon source, as indicated, the hydrocarbon source includes, comprises, consists essentially of, consists of, or is a gas or vapor, which is fed into the chamber. The hydrocarbon source can be considered a carbon source that can pyrolyze to form carbon deposits.

The hydrocarbon source can comprise or include or be natural gas.

Other examples of the hydrocarbon source include, but are not limited to, propane. The hydrocarbon source can comprise or include or be a vapor of bio-oil, recycled oil, sustainable oil; a byproduct of biofuel or biochemical production, or an oil derived from tires, for example, from tire pyrolysis, oil derived from plastic pyrolysis or recycling, or an oil from hydrothermal liquefaction or paper processing.

Other specific examples of a hydrocarbon source include the following:
Glycerin from the production of bio-diesel.
Other hydrocarbon byproducts of biofuel production, e.g., distiller's corn oil.
The vaporizable fraction of hydrocarbons from hydrothermal liquefaction
Crude tall oil, the vaporizable component of tall oil pitch, turpentine, resin, or tall oil fats.
Waste cooking oil.
Biomethane or renewable natural gas produced from the decomposition of sludge, sewage, agricultural waste, or landfill material.
Oil derived from lignin.
Vegetable oils, edible or non-edible (e.g., jatropha oil).
Tire pyrolysis oil derived from the pyrolysis of tires or rubber articles made from natural rubber.
Hydrocarbon derived from seaweed, algae or other non-crop plants.
Hydrocarbon derived from or produced by cyanobacteria.
Hydrocarbon derived from black liquor in the paper process.
Vaporizable oil derived from animal waxes or fats, e.g., lanolin, lard or tallow.
Oil rendered from the pyrolysis, thermal decomposition, or rendering of animal processing byproducts, e.g., turkey carcasses.

A recycled oil or vaporizable hydrocarbon can be:
Vaporizable component of used motor oil.
Oil or hydrocarbon gas derived from the pyrolysis of plastic waste.
Oil or hydrocarbon gas derived from the pyrolysis of municipal solid waste.
Oil or hydrocarbon gas derived from the pyrolysis of end-of-life or scrap tires.

The hydrocarbon source can be from one source or a mixture of two or more sources.

The hydrocarbon source can be fed into the chamber as one feed or multiple feeds. For instance, the hydrocarbon source can be fed (e.g., injected) into the chamber by one or multiple jets or feed lines. The multiple feed lines can be located or distributed about the chamber so that the hydrocarbon source is uniformly distributed in the chamber which can result in better distribution of the carbon deposits onto the base particles, that result from the pyrolyzing of the hydrocarbon.

The amount of the hydrocarbon source can be an amount based on the amount of particles being coated and/or the desired coating thickness and may depend on the carbon content and pyrolysis behavior of the hydrocarbon source. For instance, the amount of the hydrocarbon source can be 0.01 kg or more per 1 kg of particles, or 0.1 kg or more per 1 kg of particles, or at least 0.15 kg per 1 kg of particles. Other amounts below or above these ranges can be utilized as well. The hydrocarbon source or the gas or vapor containing the hydrocarbon source can be a gas or vapor. The amount of hydrocarbon source comprising the gas or vapor can be any amount. The amount of hydrocarbon source in the gas or vapor can be, for instance, at least 25% by volume, or at least 50% by volume, or at least 75% by volume, or at least 80% by volume, or at least 90% by volume, or at least 95% by volume, or at least 99% by volume.

The amount of hydrocarbon source that pyrolyzes is preferably 100% or about 100% by volume. Amounts less than 100% by volume are possible (e.g., from 50% to 99% or from 75% to 99%, or from 85% to 99% or other amounts by volume based on total volume of hydrocarbon source present). If amounts of the hydrocarbon source are not pyrolyzed, these unused amounts can optionally be recycled and used in subsequent batches to form carbon coated particles.

As an option, the hydrocarbon may be heated in addition to or as an alternative to heating the base particles. The hydrocarbon may be heated to a temperature of at least 800° C., at least 900° C., at least 1000° C., at least 1100° C., at least 1200° C., at least 1300° C., at least 1400° C., or at least 1500° C., for example from 900 to 1200° C. or from 1300 to 1600° C.

As an option, an oxidizing atmosphere can be present in the chamber for at least a part of residence time that the base particles spend in the chamber. The oxidizing atmosphere can be at least achieved by the introduction of water into the chamber. Preferably, the oxidizing atmosphere is present in the early or initial stages of the residence time of the base particles in the chamber (e.g., present during the first half, or first third, or first quarter of the residence time). Preferably, oxygen is not introduced into the chamber during pyrolysis of the hydrocarbon source, thus retarding or preventing the generation of carbon dioxide and carbon monoxide. More preferably, carbon dioxide and carbon monoxide are not introduced into the chamber during pyrolysis, thus reducing or eliminating carbon dioxide and/or carbon monoxide in the gas stream discharged from the chamber after pyrolysis.

As another option, the methods of the present invention can include conducting steam oxidation of the base particles in the chamber. The steam oxidation can occur at any point during the residence time in the chamber. Preferably, this option occurs at the early or initial stages of the residence time of the base particles in the chamber (e.g., present during the first half, or first third, or first quarter of the residence time).

As an option, the methods of the present invention can further include heating the carbon coated particles, in a second step (subsequent step), in either the same chamber or a different chamber, in a neutral atmosphere or a reducing atmosphere. Thus, once the base particles are coated with carbon by a method of the present invention, this further step can occur. The further heating can be achieved with the same or different energy source as used in the coating step or can be a completely different energy source, such as, but not limited to, a rotary kiln, a furnace, a carbon black reactor (e.g., a multi-staged carbon black reactor or a furnace carbon black reactor), or a modified carbon black reactor (e.g., a carbon black reactor that does not include any injection port for a carbon black forming feedstock). The heating chamber can be a thermally insulated chamber(s). The rotary kiln can be a direct-fired rotary kiln or can be indirect-fired rotary kiln. The rotary kiln can be a Feeco rotary kiln.

The heating in this optional second step can be a temperature of at least 300 deg C., or at least 500 deg C., or at least 800 deg C. The heating, if utilized, can be dependent on the function of the heating. If heating is used to promote or further promote pyrolyzing, higher heating temperatures can be more desirable (at least 500 C or at least 800 C). If heating is used to promote or further promote the driving off of volatiles, lower heating temperatures may be sufficient (e.g., at least 300 deg C.). This optional heating can benefit in that non-carbon substances can be vaporized or otherwise removed or at least a portion of these types of substances. The residence time for this second optional step can be at least 10 seconds or at least 10 minutes or at least 1 to 2 hours.

As an option, a non-reacting carrier gas or non-reactive carrier gas can be present with the hydrocarbon source as a mixture or co-introduced into the chamber, or introduced before and/or after the introduction of the hydrocarbon source. Examples of such gases include, but are not limited to, nitrogen, argon, helium, or any combinations thereof. The amount of this optional gas can be up to 20:80 (volume ratio of hydrocarbon:non-reacting gas). Amounts below or above this ratio are possible.

As indicated, the hydrocarbon gas can be introduced into the chamber in two or more locations in the chamber. And, as an option, the optional non-reacting carrier gas can be introduced into the chamber either separately or with the hydrocarbon gas in two or more locations in the chamber.

With respect to the introduction or feeding of the base particles into the chamber, the base particles can be fed into the chamber as batches, continuously, or semi-continuously. For instance, the base particles can be placed on a tray that is then introduced into the chamber. Or, as an option, the base particles can be feed into the chamber using a conveyor or other mechanical device that moves or feeds particles from one location to another.

The feed rate of base particles into the chamber can be any feed rate and can depend on the size of the chamber and energy source. Examples of suitable feed rates can be at least 100 kg/hr or at least 250 kg/hr, or at least 500 kg/hr, or at least 750 kg/hr, or at least 1000 kg/hr, or at least 2,000 kg/hr, or at least 3,000 kg/hr, or at least 4,000 kg/hr, or at least 5,000 kg/hr particles. The base particles can be positioned or located on a fixed bed within the chamber or can be placed on a tray or moving platform or conveyor for introduction into the chamber.

As an option, the base particles can be on a moving bed that passes through the chamber.

In the methods of the present invention, when the hydrocarbon source pyrolyzes, and the carbon deposits are formed, the carbon deposits can entirely coat the base particles. In the alternative, the carbon can almost entirely deposit on the base particles such that at least 75%, or at least 80%, or at least 90% or at least 95% or at least 98%, or at least 99% of the outer exposed surface area of the base particles are coated by the carbon deposits.

The resulting carbon coated base particles may have a ratio of the area Raman D band to the area of the Raman G band (I_{D}/I_{/G}) of 0.5 to 2.45, for example, from 1 to 2.45 or from 1.5 to 2.45. Raman measurements are based on Gruber et al., “Raman Studies of Heat-Treated Carbon Blacks,” Carbon Vol. 32 (7), pp. 1377 1382, 1994, which is incorporated herein by reference. The Raman spectrum of carbon includes two major “resonance” bands at about 1340 cm⁻¹ and 1580 cm⁻¹, denoted as the “D” and “G” bands, respectively. It is generally considered that the D band is attributed to disordered sp² carbon and the G band to graphitic or “ordered” sp² carbon. Thus, a decrease in the D/G band ratio (also termed I_{D}/I_{G}) corresponds to a more ordered crystalline structure.

With respect to the coating on the base particles, the coating can be uniformly or substantially uniformly the same thickness around the external surface of the base particles. For instance, the thickness about the external surface of the base particles (on average) can vary less than 20%, less than 15%, less than 10%, less than 5% in thickness about the external surface of the base particles. This determination can be based on the analysis, for instance of 5% or of 2% or of 1% by weight of the coated base particles in the batch.

The coating of the carbon deposit can have an average thickness of from about 0.5 nanometer (nm) to about 500 nm or more, or from about 0.75 nm to 500 nm or more, or from about 1 nm to 500 nm or more, such as from 0.5 nm to 450 nm, from 0.5 nm to 400 nm, from 0.5 nm to 350 nm, from 0.5 nm to 300 nm, from 1 nm to 250 nm, from 1 nm to 200 nm, from 1 nm to 150 nm, from 1 nm to 125 nm, from 1 nm to 100 nm, from 1 nm to 75 nm, from 1 nm to 50 nm, from 1 nm to 25 nm, from 1 nm to 20 nm, from 1 nm to 15 nm, from 1 nm to 10 nm, from 1 nm to 7.5 nm, from 1 nm to 5 nm, from 1 nm to 2.5 nm, from 0.5 nm to 1 nm, from 0.5 nm to 5 nm, from 10 nm to 500 nm, from 50 nm to 500 nm, from 100 nm to 500 nm, from 250 nm to 500 nm, from 1 nm to 500 nm, from 7.5 nm to 50 nm, from 10 nm to 50 nm, from 1.25 nm to 5 nm, from 1.5 nm to 5 nm, from 2 nm to 5 nm, from 2.5 nm to 5 nm, from 3 nm to 5 nm, or any range based upon any two values described herein. The average thickness can be based, for instance, on the analysis, for instance of 5% or of 2% or of 1% by weight of the carbon coated particles in the batch.

As an option, the methods of the present invention can result where the carbon deposits at least partially coat the base particles rather than coating 100% of the base particle. With partial coating, for instance, from 25% to 75% or 50% to 95% of the external surface of the base particles (on average) are coated with the carbon deposits.

The residence time of the base particles in the chamber is generally a time sufficient for the carbon deposits to form and coat the base particles. The residence time can be dependent on the amount of base particles being heated, the type of energy source, the power or frequency of the energy source, the hydrocarbon source, and the temperature of the heating. The base particles, for instance, can have a residence time in the chamber of from 1 second to 3 hours or more. The residence time can be from 1 second to 2.75 hours, from 1 second to 2.5 hours, from 1 second to 2.25 hours, from 1 second to 2 hours, from 1 second to 1.75 hours, from 1 second to 1.5 hours, from 1 second to 1.25 hours, from 1 second to 1 hour, from 1 second to 45 minutes, from 1 second to 30 minutes, from 1 second to 15 minutes, from 1 second to 10 minutes, from 1 second to 5 minutes, from 1 second to 60 seconds, from 1 second to 30 seconds, from 5 seconds to 2 hours, from 5 seconds to 1 hour, from 5 seconds to 30 minutes, from 5 seconds to 15 minutes, from 5 seconds to 3 hours, from 30 seconds to 3 hours, from 1 minute to 3 hours, from 5 minutes to 3 hours, from 30 minutes to 3 hours, and the like.

As an option, the methods of the present invention can be conducted in the absence of any catalyst.

As an option, the methods of the present invention can be conducted in the absence of any introduced oxygen or a gas containing oxygen (e.g., a gas where oxygen comprises over 10% or over 15% or over 20% by volume based on the total volume of the gas).

As an option, the methods of the present invention can yield no carbon dioxide or carbon monoxide or essentially no carbon dioxide or carbon monoxide (e.g., the amount of carbon dioxide and/or carbon monoxide generated is less than 0.5 kg CO₂ and CO total per kg of carbon coated particles. Moreover, the decomposition of the hydrocarbon results in the production of hydrogen gas. This hydrogen gas is thus produced with no or essentially no carbon dioxide, with the carbon from the hydrocarbon deposited as a solid on the base particles. For example, the gas discharged from the chamber may have at most 0.5 kg combined carbon dioxide and carbon monoxide/kg of carbon coated particles, e.g., at most 0.2 carbon dioxide and carbon monoxide/kg carbon coated particles or at most 0.1 kg of carbon dioxide and carbon monoxide/kg carbon coated particles. The resulting hydrogen gas may be separated from other gasses discharged from the chamber by any technique known to those of skill in the art, for example, pressure swing absorption, hydrogen permeable ceramic membranes, etc.

The gas discharged from the chamber may be at least 50 volume % hydrogen. In embodiments in which oxygen-containing gases, steam, or other carrier gases are not introduced to the chamber or are introduced in only limited amounts, the gas discharged from the chamber may be at least 60 volume %, at least 70 volume %, at least 80 volume %, or at least 90 volume % hydrogen, for example, from 60 volume % to 90 volume %, from 70 volume % to 95 volume %, or from 80 volume % to 99 volume %. The resulting hydrogen may be used as a fuel source. In some embodiments the gas discharged from the chamber may be used as a fuel source without further purification processes.

The base particles that are heated by the energy source in the chamber are heated, for instance, to a temperature of at least 800 deg C., or at least 900 deg C., or at least 1200 deg C., or at least 1500 deg, such as from 800 deg C. to 1600 deg C. or from 800 deg C. to 1400 deg C., or from 800 deg C. to 1300 deg C., or from 800 deg C. to 1200 deg C., or from 800 deg C. to 1100 deg C., or from 800 deg C. to 1000 deg C., or from 800 deg C. to 900 deg C., or from 900 deg C. to 1500 deg C., or from 1000 deg C. to 1500 deg C., or from 1100 deg C. to 1500 deg C., or from 1200 deg C. to 1400 deg C., or from 1200 deg C. to 1500 deg C., or from 850 deg C. to 1500 deg C., or from 875 deg C. to 1500 deg C., or from 950 deg C. to 1500 deg C., or from 1050 deg C. to 1500 deg C., or from 1150 deg C. to 1500 deg C., or from 1250 deg C. to 1500 deg C., or from 1350 deg C. to 1500 deg C., or from 800 deg C. to 1450 deg C., or from 850 deg C. to 1450 deg C., or temperatures above 1500 deg C., or any temperature ranges using any end points from any combination of ranges.

The reference to the temperature relating to the heating of the particles here and throughout (for any other step(s)) is a temperature that is calculated based on thermodynamic calculations (without including any heat losses through the chamber or reactor wall) of the materials inputted into the reactor. As an option, the chamber can have more than one zone where heating occurs. When more than one zone is present for the heating chamber, the one or more of the other zones can be utilized as additional heat treatment zones (i.e., have zone temperatures of at least 300 deg C. or at least 500 deg C. or at least 800 deg C.) or can be utilized as quench zones and/or for other purposes. If more than one zone is utilized to achieve zone temperatures of at least 300 deg C. or at least 500 deg C. or at least 800 deg C., each of these zones can have the same or similar or different temperatures of heating. The residence times for each of these zones, if utilized, can be the same, similar or different. The temperatures and/or residence times of each of these zones, if utilized, can be within 1%, within 5%, within 10%, within 20%, within 30%, within 40%, within 50%, within 75% of each other or can be different at least by any one of the % provided here.

If the chamber has more than one heating zone, the energy source utilized in each zone can be the same or different.

As an option, the chamber can comprise at least a first chamber and a second chamber. In such a set-up, in the first chamber, the base particles are subjected to at least one of the energy sources (e.g., the microwave energy or induction energy) such that the base particles reach an average surface temperature of at least 800 deg C., at least 900 deg C., at least 1000 deg C., at least 1100 deg C., at least 1200 deg C., at least 1300 deg C., at least 1400 deg C., at least 1500 deg C. or at least 1600 deg C. (e.g., from 800 deg C. to 1600 deg C. or from 800 deg C. to 1500 deg C., or from 1000 deg C. to 1300 deg C.) in the absence of any hydrocarbon source to obtain heated base particles. Then, the heated base particles are transported to the second chamber where the feeding of the hydrocarbon source occurs (and any of the other optional features with the hydrocarbon source).

In the second chamber, further heating of the base particles can occur or not occur. Due to the elevated temperature that the particles may be heated to, this elevated temperature can be sufficient such that no further heating needs to occur in the second chamber, and the temperature causes the pyrolyzing of the hydrocarbon source in the second chamber. Though not required, as an option, the base particles in the second chamber can be subjected to further heating by a further energy source or the same energy source as in the first chamber. The type of energy source can be the same or different from the energy source utilized in the first chamber.

When a further heating source is utilized in the second chamber, the heating source can maintain the heated base particles at an average surface temperature of at least 800 deg C., at least 900 deg C., at least 1000 deg C., at least 1100 deg C., at least 1200 deg C., at least 1300 deg C., at least 1400 deg C., at least 1500 deg C. or at least 1750 deg C. or at least 2000 deg C. (e.g., from 800 deg C. to 2200 deg C. or from 800 deg C. to 2000 deg C., or from 1000 deg C. to 1800 deg C.) As an option, the heated base particles are on a moving bed in the second chamber.

As an option, at least one catalyst can be utilized during the method of the present invention. For instance, the catalyst can be a metal catalyst or an inorganic catalyst. As a further option, recycled iron or limestone can be used and applied to at least a portion of the surface of the base particles prior to being subjected to the energy source. The catalyst, in the methods of the present invention, are preferably covered by the carbon deposits that coat the base particles and therefore are not exposed or visible on the surface of the coated base particles. The amount of catalyst can be consistent with the amounts used for conventional or ordinary waste contamination processes. The catalyst, can be, but is not limited to, potassium, sodium, magnesium, calcium, aluminum, nickel, iron, or catalyst-based material with one or more of these metals or any combinations thereof. It may be advantageous to deliberately add known pyrolysis catalyst such as iron, for instance, at up to 10% by weight (other amounts can be used).

When two or more chambers are used, as an option, the base particles, if not deaggregated already, can be deaggregated, at least in part, in the first chamber.

When two or more chambers are used, the chambers, for instance, the first chamber compared to the second chamber, can be of different sizes with respect to volume. As an example, the first chamber can be at least 25% smaller in volume or at least 50% smaller in volume compared to the volume of the second chamber (e.g., from 25% to 75% smaller in volume compared to the volume of the second chamber).

Applying some of the major aspects of the methods of the present invention to particles other than carbon particles, the present invention can provide methods to carbon coat non-carbon particles, such as silica, preferably precipitated silica particles.

For instance, the present invention further relates to a method to form carbon coated precipitated silica particles. The method includes introducing precipitated silica particles into a chamber and subjecting the precipitated silica particles to one of the energy sources described herein, such as microwave energy or induction energy, to form heated precipitated silica particles. The method further includes feeding a hydrocarbon source that comprises or is a gas or vapor into the chamber. The hydrocarbon source pyrolyzes, at least in part, in the chamber to form carbon deposits, thereby coating the heated precipitated silica particles with the carbon deposits and form the carbon coated precipitated silica particles.

The various details and examples and operating parameters and other aspects of the methods described earlier with respect to carbonaceous base particles as the particle being coated applies equally here to this part of the present invention.

With the present invention, it was discovered that the size of the base particles can affect the ability of achieving a carbon coated particle. The particles coated, while in particulate form, can be in the form of larger aggregates (especially from commercial sources that supply the particles). Thus, an aspect of the present invention can involve taking steps to reduce the size of the particles that are to be coated, so that their size results in a carbon coated particle.

Alternatively, deaggregation can occur in the same chamber and by way of the same heating of the particles that results in the pyrolyzing of the hydrocarbon source.

With respect to the method steps of deaggregating a particle (such as an rC aggregate), the methods described in U.S. Patent Application No. 63/493,812 filed Apr. 3, 2023 (incorporated in its entirety by reference herein) can be utilized here prior to the steps of coating the particles. As a summary, the method to at least partially deaggregate particles, such as carbon particles, for example rC aggregates comprises, consists essentially of, consists of, or includes introducing the particles, such as rC aggregates (e.g., the starting IC aggregates) into a heating chamber having one or more zones. As part of this method, the heating chamber has at least one zone that has a zone temperature of at least 800 deg C. or at least 900 deg C. The starting particles, such as rC aggregates, are in the at least one zone that has the zone temperature for a residence time sufficient to result in deaggregation of at least a portion of the particles, such as rC aggregates. Thus, the method results in obtaining deaggregated particles such as deaggregated rC aggregates (i.e., aggregates with small aggregate sizes or aggregates that have a smaller aggregate size compared to the starting aggregate size of the starting rC aggregates). Other steps before and/or after the deaggregation can occur.

The aggregate size distribution can be measured using TEM images of the particles following the ASTM D3849 method. About 20 mg of the particles are added to 13 mL chloroform in a beaker, then sonicated surrounded by an ice bath for 10 min at 50% amplitude using Misonix XL2020 with a sonication probe of a half-inch tip. The sonicated dispersion is further diluted with additional chloroform to ~100-120 ppm, then probe sonicated for an additional three minutes. A drop of this dispersion was placed onto a 200-mesh carbon coated TEM grid and allowed to dry in desiccator. The TEM images were acquired using a JEOL JEM-1200 Transmission Electron Microscope (TEM) with electron accelerating voltage at 80 kV using image resolution at 1.6 nm/pixel and a field-of-view at least 5 μm×5 μm. The images can then be analyzed following the ASTM D3849 method using automated programs based on NIH ImageJ macro language and Microsoft Excel visual basic for Applications (VBA). The projected area equivalent diameter Dcircle of a reclaimed carbon aggregate was used as the metric for the aggregate size. At least 2000 aggregates were analyzed to obtain both number weighted and volume weighted aggregate size distributions of reclaimed carbon samples.

The presence of rC aggregates larger than 1 micron is believed to be a major contributor to its low rubber reinforcement properties when used as a partial or complete substitute for virgin carbon black. Aggregates larger than 1 micron can account for a large amount of the total rC aggregates by mass. Thus, it is believed that a substantial percentage of the starting rC aggregates or other similarly size aggregates, if used “as-is” does not provide positive rubber reinforcement properties or actually is a detriment to obtaining positive rubber reinforcement properties.

Furthermore, the starting aggregates larger than 1 micron in aggregate size (e.g., 1.1 microns to 10 microns or higher) are believed to substantially reduce fatigue life and abrasion resistance when used in compositions such as elastomer products. For instance, elastomeric products made using starting rC aggregates can have 5 to 10 times the number of large undispersed particles as compared to typical carbon black containing elastomeric composites that contain virgin carbon black instead of starting rC aggregates.

The undispersed large rC particles or other particles can be important factors that lead to a reduction of fatigue life in for instance a tire sidewall formulation containing rC (e.g., up to a 60% reduction of fatigue life via DeMattia fatigue test) as compared to a sidewall formulation containing virgin carbon black.

The figures are provided to show aspects of the present invention in a simplified schematic manner.

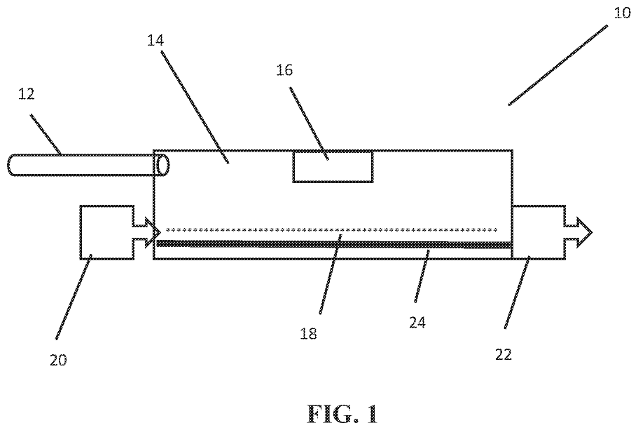

FIG. 1 provides a general cross-sectional view of a set-up for an embodiment of the present invention. The overall system or device 10 can have at least one chamber 14 where the heating of the particles (e.g., carbon particles 18) occurs. The particles are introduced via an inlet or entry or door 20 and once the process is completed, the carbon coated particles can either exit the same way through inlet 20 or can exit via an outlet or door 22. The particles can be on a bed or other support surface 24. This can be a stationary or moving bed. Hydrocarbon gas or vapor can be introduced into chamber 14 via a tube or injector or feed 12. More than one feed can be present and be located uniformly across the chamber if desired. An energy source 16 is located in the chamber 14 or adjacent the chamber 14. The location of the energy source (or a portion thereof) can be below or above or around the particles 18.

Once the carbon coated particles are formed, the carbon coated particles exit by way of the outlet of the chamber so that the carbon coated particles can be recovered. The carbon coated particles can be cooled down for the recovery step, such as by one or more quenching steps, which can be in one or more quench zones. The carbon coated particles can be recovered in the same or similar manner that virgin carbon black is recovered from carbon black reactors.

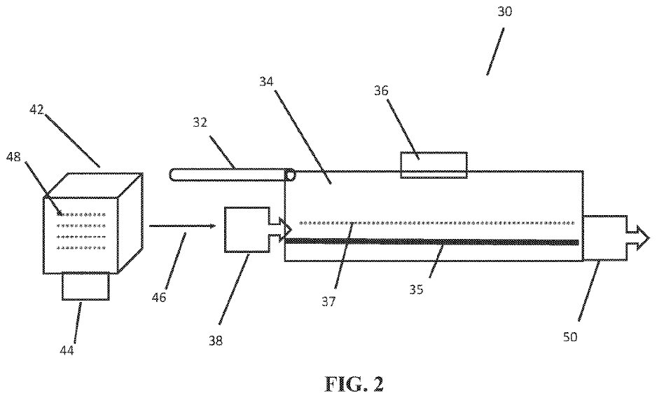

FIG. 2 provides a cross-sectional simplified view of a further embodiment of an overall system or set-up 30 of the present invention where two chambers are used. The first chamber 42 can first receive the particles 48 (e.g., carbon particles or other particles) and heating can occur in the first chamber in the absence of the hydrocarbon source. The heating can be in an oxygen atmosphere, an inert atmosphere, or in a vacuum. The heating of the particles in the first chamber can either provide heated particles that will be hot enough such that when placed in contact with a hydrocarbon source (in the second chamber 34, the hydrocarbon source being introduced by way of tube or feed 32 is pyrolyzed and coats the particles 37, and/or the heating can be used to deaggregate the particles 48. The heating of the first chamber can be achieved with any energy source 44 as described herein or other types of energy sources (e.g., oven, kiln, and the like). The location of the energy source (or a portion thereof) can be below or above or around the particles 48. Once heating is achieved in the first chamber 42, the heated particles can be transferred 46 by any conventional means (e.g., tray, conveyer belt, container, feed) to an inlet or entry or door 38 into the second or main chamber 34, where the heated particles 37 can be subjected to the hydrocarbon containing gas or vapor that can be introduced into chamber 34 via a tube or injector or feed 32. After the particles are coated, the particles can either exit the same way through inlet 38 or can exit via an outlet or door 50. The particles can be on a bed or other support surface 35. This can be a stationary or moving bed. More than one feed can be present and be located uniformly across the chamber if desired. An energy source 36 can optionally be located in the chamber 34 or adjacent the chamber 34. The further energy source 36 can be used to keep the particles at a desired temperature and/or can be used to remove volatiles from the particles. The location of the energy source (or a portion thereof) can be below or above or around the particles 37.

As an option, the base particles may be coated in a two step process. For example, particles 18 exiting chamber 14 may be directed to a further chamber similar to either chamber 14 or chamber 34 to be coated with additional carbon. The further chamber may be maintained at a higher or lower temperature than chamber 14. Alternatively or in addition, particles 38 exiting chamber 34 may be directed to a further chamber similar to either chamber 14 or chamber 34 to be coated with additional carbon. The further chamber may be maintained at a higher or lower temperature than chamber 34. The use of a higher or lower temperature may influence one or more of the kinetics of carbon deposition and the proportion of disordered and graphitic carbon as described by I_{D}/I_{G}. Without being bound by any particular theory, it is believed that higher temperatures correlate with lower ratios I_{D}/I_{G} and therefore with higher proportions of graphitic carbon and/or larger graphitic crystallite sizes La.

As an option, the starting base particles, prior to the starting base particles being introduced into the chamber, can be subjected to one or more size reducing processes such as mechanical milling. The mechanical milling can reduce the size of any agglomerates to form the starting carbon particles or other particles. Mechanical milling will not, however, reduce the aggregate size of such particles as rC. Generally, the mill can be configured to pulverize, grind, and/or comminute the starting carbon particles or other particles into smaller agglomerates. The mill can include a hammermill, a bead mill, a jet mill, a steam mill, and/or any other grinding, pulverizing, or milling machine. The milling steps and/or techniques as well as the parameters of the starting particles and milled particles as described in International (PCT) Publication No. WO2023122582 filed Dec. 20, 2022, incorporated in its entirety by reference herein, can be utilized here for purposes of the present invention.

The mill can be directly coupled to the inlet of the chamber. For example, rC or other particles can be fed into the mill and the mill directly feeds the milled rC or other particles to the chamber. As an option, the mill can be separate from the chamber, in which the particles, such as rC, are first milled and then transported to the inlet of the chamber.

After the carbon coated particles are formed, the method of the present invention can include the step of quenching.

As an option, the outlet of the chamber can lead to an inlet of a quenching chamber or quench zone. The quenching chamber can spray a quenching fluid, such as water, onto the carbon coated particles. In general, the quench serves to cool the starting base particles. Optionally, quenching may be staged, or take place at several points in the quenching chamber. A pressure spray, a gas-atomized spray or other quenching techniques can be utilized. With respect to completely quenching the carbon coated particles or other particles, any conventional means to quench the carbon coated particles or other particles downstream of the chamber can be used and is known to those skilled in the art. For instance, a quenching fluid can be injected which may be water or other suitable fluids to cool the carbon coated particles or other particles.

After quenching, the cooled carbon coated particles or other particles pass downstream into any conventional cooling and separating means whereby the carbon coated particles are recovered. Any conventional means for recovering the coated particles can be used, and these means can include, but are not limited to, a precipitator, cyclone separator, bag filter or other means known to those skilled in the art. After the carbon coated particles are recovered, they can be optionally subjected to a pelletization step, similar to virgin carbon black.

To pelletize the carbon coated particles in a mixer, a spray nozzle can wet the carbon coated particles or other particles with a binding agent, such as water, toluene, mineral oil, or the like. The mixer mixes the binding agent and carbon coated particles into a substantially homogenous mixture that agglomerates (or clumps) into pellets of the carbon coated particles. The pellets can then be dried to a particular moisture content, such as less than 1% by weight. By reducing the moisture content of the pellets, the method of the present invention can prevent introduction of undesired moisture into rubber mixing that can contribute to gas emissions (or off-gassing) that are emitted when the pellets are heated within a rubber mixer and/or plastic master batching mixer. These gas emissions can carry toxic components, such as polycyclic aromatic hydrocarbons, into the air of a manufacturing facility when residual moisture within the agglomerates evaporate under heat.

The carbon coated particles of the present invention can be used as a substitute or combined with carbon black or other reinforcement agents as a component in elastomer or rubber products. The carbon coated particles can be used as a reinforcement agent or filler in materials, such as in rubber products, e.g., tire components.

The carbon coated particles of the present invention can be incorporated in rubber articles, being used, for instance, for tire tread, especially in tread for passenger car, light vehicle, truck and bus tires, off-the-road (“OTR”) tires, airplane tires and the like; sub-tread; wire skim; sidewalls; cushion gum for retread tires; and other tire uses.

In other applications, the carbon coated particles of the present invention can be used in industrial rubber articles, such as engine mounts, hydro-mounts, bridge bearings and seismic isolators, tank tracks or tread, mining belts, hoses, gaskets, seals, blades, weather stripping articles, bumpers, anti-vibration parts, and others.

The carbon coated particles of the present invention can be added as an alternative or in addition to first reinforcing agents for tire components and/or other industrial rubber end-uses. The carbon coated particles of the present invention can be combined with natural and/or synthetic rubber in a suitable dry or wet mixing process based on an internal batch mixer, continuous mixer or roll mill.

The performance of the carbon coated particles of the present invention as a reinforcing agent for rubber compounds can be assessed by determining, for example, the performance of a rubber composition utilizing the carbon coated particles of the present invention relative to the performance of a comparative rubber composition that is similar in all respects except for the use of carbon coated particles of the present invention. In other approaches, values obtained for compositions prepared according to the present invention can be compared with values known in the art as associated with desired parameters in a given application.

Carbon coating rC or other particles using the processes provided herein may improve the performance of rubber compounds prepared with the carbon coated material with respect to the uncoated base particle. For example, carbon coating rC may improve reinforcement properties such as tensile modulus, hysteresis (as measured by tan delta), tear strength, and/or fatigue life. The performance of rubber compounds prepared with the coated rC may be comparable to the performance of rubber compounds prepared with virgin carbon black. Alternatively or in addition, the performance of rubber compounds prepared with the coated rC may be comparable to the performance of rubber compounds prepared with uncoated rC. In either of these embodiments, performance may be determined by one or more of tensile modulus at 100% strain, tensile modulus at 300% strain, elongation at break, tan delta (60 degC), tear strength (ASTM D624, Die B), and/or fatigue life (ASTM D4482). For any of these properties, performance may be improved by at least 5%, at least 10%, at least 15%, or at least 20%, for example, by 5-25%, by 10-20%, by 5-15%, or by 15-30%. Tensile modulus and elongation at break are measured according to ASTM D412 (Test method A, Type C) at 23° C., 50% relative humidity and at crosshead speed of 500 mm/min. Tan delta 60° is determined using a dynamic strain sweep between 0.01% and 60% at 10 Hz and 60° C. Tan δₘₐₓ (sometimes written tan delta) is taken as the maximum value of tan δ within this range of strains. Fatigue life is measured according to ASTM D4482.

Unless otherwise specified, all material proportions described as a percent herein are in weight percent.

The present invention includes the following aspects/embodiments/features in any order and/or in any combination:
1. The present invention includes a method to form carbon coated base particles, for example carbon coated carbon particles, said method comprising introducing base particles into a chamber and subjecting the base particles to an energy source that is at least one of hot gas, microwave energy, induction energy, direct current passing through said base particles, electromagnetic radiation, or solar radiation, so as to form heated base particles, and feeding a hydrocarbon source that comprises a gas or vapor into said chamber, wherein the hydrocarbon source pyrolyzes, in at least in part, in said chamber to form carbon deposits, and thereby coating said heated base particles with said carbon deposits and form said carbon coated base particles, wherein the base particles optionally comprise reclaimed carbon particles.
2. The method of any preceding or following embodiment/feature/aspect, wherein the base particles comprise carbon particles or particles that have at least 10% or at least 75% carbon content.
3. The method of any preceding or following embodiment/feature/aspect, wherein the base particles comprise solid hydrothermal carbon (HTC), carbon particles that are non-ASTM reinforcement grade particles, silicon-treated carbon black, silica coated carbon black, graphene, reduced graphene oxide, single walled carbon nanotubes, multi walled carbon nanotubes, carbon nanostructures, carbon black coated particles, biochar, and any combination of these.
4. The method of any preceding or following embodiment/feature/aspect, wherein the base particles comprise graphene oxide, lignin, or nanocrystalline cellulose, bio-based particles, polysaccharides, engineered polysaccharides, or any combination of these.
5. The method of any preceding or following embodiment/feature/aspect, wherein the reclaimed carbon particles comprise deaggregated and/or milled reclaimed carbon particles.
6. The method of any preceding or following embodiment/feature/aspect, wherein the base particles comprise precipitated silica, rice husk silica, clays, nanoclays, diatomaceous earth, metal oxides, metal carbonates, or any combination of these.
7. The method of any preceding or following embodiment/feature/aspect, wherein the base particles are subjected to the microwave energy.
8. The method of any preceding or following embodiment/feature/aspect, wherein said microwave energy is at least 0.5 GHz, for example, from 0.5 GHz to 10 GHz.
9. The method of any preceding or following embodiment/feature/aspect, wherein the base particles are subjected to the induction energy.
10. The method of any preceding or following embodiment/feature/aspect, wherein the induction energy is provided by an induction heater operated at a frequency of at least 5 KHz.
11. The method of any preceding or following embodiment/feature/aspect, wherein the induction energy is provided by an induction heater operated at a frequency of from 5 kHz to 500 KHz.
12. The method of any preceding or following embodiment/feature/aspect, wherein the induction heater operates at an induction heater power of at least 50 MJ/kg.
13. The method of any preceding or following embodiment/feature/aspect, wherein the induction heater operates at an induction heater power of from 50 MJ/kg to 250 MJ/kg.
14. The method of any preceding or following embodiment/feature/aspect, wherein the chamber comprises a fluidized bed reactor, an ablative pyrolysis reactor, a vacuum pyrolysis reactor, a fixed bed drop-type reactor, or a solar pyrolyzer.
15. The method of any preceding or following embodiment/feature/aspect, wherein the microwave energy or induction energy is produced from renewable electricity.
16. The method of any preceding or following embodiment/feature/aspect, wherein the base particles are bio-based particles.
17. The method of any preceding or following embodiment/feature/aspect, wherein the hydrocarbon source comprises natural gas.
18. The method of any preceding or following embodiment/feature/aspect, wherein the hydrocarbon source consists of natural gas.
19. The method of any preceding or following embodiment/feature/aspect, wherein the method is conducted in the absence of a catalyst.
20. The method of any preceding or following embodiment/feature/aspect, wherein the method is conducted in the absence of introduced oxygen.
21. The method of any preceding or following embodiment/feature/aspect, wherein the method yields at most 0.5 kg carbon dioxide and carbon monoxide/kg carbon coated particles, for example, no carbon dioxide or carbon monoxide.
22. The method of any preceding or following embodiment/feature/aspect, wherein the base particles are heated to a temperature of at least 800 deg C.
23. The method of any preceding or following embodiment/feature/aspect, wherein the base particles are heated to a temperature of at least 900 deg C.
24. The method of any preceding or following embodiment/feature/aspect, wherein the base particles are heated to a temperature of at least 1000 deg C.
25. The method of any preceding or following embodiment/feature/aspect, wherein the base particles are heated to a temperature of at least 1500 deg C.
26. The method of any preceding or following embodiment/feature/aspect, wherein the hydrocarbon source comprises a vapor of bio-oil, recycled oil, sustainable oil; a byproduct of biofuel or biochemical production, or an oil derived from tires, for example, from tire pyrolysis, oil derived from plastic pyrolysis or recycling, or an oil from hydrothermal liquefaction or paper processing.
27. The method of any preceding or following embodiment/feature/aspect, wherein the base particles are on a fixed bed within the chamber.
28. The method of any preceding or following embodiment/feature/aspect, wherein the base particles are on a moving bed that passes through the chamber.
29. The method of any preceding or following embodiment/feature/aspect, wherein the carbon deposits uniformly coat the base particles.
30. The method of any preceding or following embodiment/feature/aspect, wherein the carbon deposits at least partially coat the base particles.
31. The method of any preceding or following embodiment/feature/aspect, wherein the product carbon coated base particles have a coating with an average thickness of from 0.5 to 500 nanometers.
32. The method of any preceding or following embodiment/feature/aspect, wherein the base particles have a residence time in said chamber of from 1 second to 3 hours.
33. The method of any preceding or following embodiment/feature/aspect, wherein the base particles have a residence time in said chamber of from 5 seconds to 2 hours.
34. The method of any preceding or following embodiment/feature/aspect, wherein the chamber comprises at least a first chamber and a second chamber, wherein in the first chamber, the base particles are subjected to the microwave energy or induction energy such that the base particles reach an average surface temperature of at least 800 deg C. in the absence of any hydrocarbon source to obtain heated base particles, and then transporting said heated base particles to the second chamber where said feeding of the hydrocarbon source occurs.
35. The method of any preceding or following embodiment/feature/aspect, wherein in the second chamber, the second chamber has a heating source that maintains the heated base particles at a surface temperature of at least 800 deg C.
36. The method of any preceding or following embodiment/feature/aspect, wherein the heated base particles are on a moving bed in the second chamber.
37. The method of any preceding or following embodiment/feature/aspect, wherein recycled iron or limestone is applied to at least a portion of the surface of the base particles prior to being subjected to said energy source.
38. The method of any preceding or following embodiment/feature/aspect, wherein the base particles are deaggregated, at least in part, in said first chamber.
39. The method of any preceding or following embodiment/feature/aspect, wherein an oxidizing atmosphere is present in said chamber for at least a part of said method.
40. The method of any preceding or following embodiment/feature/aspect, wherein an oxidizing atmosphere is present in said chamber for at least a part of said method that is at least achieved by the introduction of water into the chamber.
41. The method of any preceding or following embodiment/feature/aspect, further comprising conducting steam oxidation of the base particles in said chamber.
42. The method of any preceding or following embodiment/feature/aspect, further comprising heating said carbon coated particles in a second step, in either the same chamber or a different chamber, in a neutral atmosphere or a reducing atmosphere.
43. The method of any preceding or following embodiment/feature/aspect, wherein a non-reacting carrier gas is present with the hydrocarbon source.
44. The method of any preceding or following embodiment/feature/aspect, wherein the hydrocarbon gas is introduced into the chamber in two or more locations in the chamber.
45. The method of any preceding or following embodiment/feature/aspect, wherein the non-reaction carrier gas is introduced into the chamber either separately or with said hydrocarbon gas in two or more locations in the chamber.
46. The method of any preceding or following embodiment/feature/aspect, wherein the first chamber is at least 25% smaller in volume compared to a volume of the second chamber.
47. The method of any preceding or following embodiment/feature/aspect, wherein the first chamber is at least 50% smaller in volume compared to a volume of the second chamber.
48. The method of any preceding or following embodiment/feature/aspect, further comprising introducing the carbon coated base particles into an additional chamber and subjecting the base particles to an energy source that is at least one of hot gas, microwave energy, induction energy, direct current passing through said base particles, electromagnetic radiation, or solar radiation, so as to form heated carbon coated base particles, and feeding a hydrocarbon source that comprises a gas or vapor into said additional chamber, wherein the hydrocarbon source pyrolyzes, in at least in part, in said additional chamber to form carbon deposits, and thereby coating said heated carbon coated base particles with additional carbon deposits.
49. The present invention further relates to a method to form carbon coated precipitated silica particles, said method comprising: introducing precipitated silica particles into a chamber and subjecting the precipitated silica particles to microwave energy or induction energy to form heated precipitated silica particles, and feeding a hydrocarbon source that comprises a gas or vapor into said chamber, wherein the hydrocarbon source pyrolyzes, in at least in part, in said chamber to form carbon deposits, and thereby coating said heated precipitated silica particles with said carbon deposits and form said carbon coated precipitated silica particles.
50. The present invention further relates to coated carbon particles or other particles formed by any method of any preceding or following embodiment/feature/aspect.
51. The present invention further relates to a method of producing hydrogen, comprising performing the method of any of the preceding embodiments/features/aspects, wherein pyrolysis of the hydrocarbon source results in the production of a gas stream comprising hydrogen.
52. The method of any preceding or following embodiment/feature/aspect, further comprising separating hydrogen from the remaining portion of the gas stream to obtain a purified hydrogen stream.
53. The method of any preceding or following embodiment/feature/aspect, further comprising the remaining portion of the gas stream to the hydrocarbon source.
54. The method of any preceding or following embodiment/feature/aspect, wherein the gas stream comprises at least 60 volume % hydrogen, for example, 80-99 volume % hydrogen.
55. The present invention further relates to carbon coated particles each comprising a base particle and carbon deposits disposed about the external surface of the base particle, the carbon coated particles having a ratio of the areas of the Raman D band (1340 cm⁻¹) and the Raman G band (1590 cm⁻¹) of 0.5 to 2.45, for example, from 1 to 2.45 or from 1.5 to 2.45.
56. The carbon coated particles of any preceding or following embodiment/feature/aspect, wherein the base particles comprise carbon particles or particles that have at least 10 wt % or at least 75 wt % carbon content.
57. The carbon coated particles of any preceding or following embodiment/feature/aspect, wherein the base particles comprise reclaimed carbon particles.
58. The carbon coated particles of any preceding or following embodiment/feature/aspect, wherein the base particles comprise carbon particles that are non-ASTM reinforcement grade particles, solid hydrothermal carbon (HTC), silicon-treated carbon black, silica coated carbon black, graphene, reduced graphene oxide, single walled carbon nanotubes, multi walled carbon nanotubes, carbon nanostructures, carbon black coated particles, biochar, and any combination of these.
59. The carbon coated particles of any preceding or following embodiment/feature/aspect, wherein the base particles comprise graphene oxide, lignin, nanocrystalline cellulose, bio-based particles, polysaccharides, engineered polysaccharides, or any combination of these.
60. The carbon coated particles of any preceding or following embodiment/feature/aspect, wherein the reclaimed carbon particles comprise deaggregated and/or milled reclaimed carbon particles.
61. The carbon coated particles of any preceding or following embodiment/feature/aspect, wherein the base particles comprise precipitated silica, rice husk silica, clays, nanoclays, diatomaceous earth, metal oxides, metal carbonates, or any combination of these.
62. The carbon coated particles of any preceding or following embodiment/feature/aspect, wherein the coating of carbon deposit has an average thickness of 0.5 nm to 500 nm.
63. A rubber article incorporating the carbon coated particles of any preceding or following embodiment/feature/aspect.
64. The rubber article of any preceding or following embodiment/feature/aspect, wherein the rubber article is a tire component selected from the group consisting of tire tread, sub-tread, wire skim, side wall, and cushion gum, an engine mount, a hydro-mount, a bridge bearing, a seismic isolator, a tank track, a tank tread, a mining belt, a hose, a gasket, a seal, a blade, a weather stripping article, a bumper or an anti-vibration part.
65. The present invention further relates to an lastomer composite comprising the carbon coated particles of any preceding or following embodiment/feature/aspect, wherein the base particle is reclaimed carbon, the elastomer composite having at least one mechanical property selected from tensile modulus at 100% strain, tensile modulus at 300% strain, elongation at break, tan delta at 60 degC, tear strength, and fatigue life with a magnitude at least 5% greater than that of an elastomer composite having the same composition but with reclaimed carbon instead of carbon coated particles.

### EXAMPLES

Example 1—Reclaimed carbon (CBP Cyprus Ltd). was fed into a tube furnace at a rate of 360 g/hr and processed with a residence time of about 1 hour at the temperature specified in Table 1 below. The tube had a 6 inch (15 cm) diameter and a heated section 60 inches (152 cm) in length and rotated at a rate of 1.8 rpm. Gas was fed into the tube at a rate of 25 scfh (708 l/h) (nitrogen) or 21 scfh (595 l/h) (methane), with an additional 6 scfh (170 l/h) of nitrogen used at all times to purge the system inlets and outlets. Samples were collected after an hour of steady state operation, meaning the flow of rC into and out of the furnace was steady, the temperature was steady, and the desired gas (nitrogen or methane) had been flowing through the tube for at least 90 minutes.

TABLE 1

| Furnace Temp | Primary Gas | | Si in | Si in | % increase | I_{D}/I_{G} (area |
|---|---|---|---|---|---|---|
| (Deg C.) | Flow | Ash (%) | ash (%) | particle (%) | in C* | ratio) |
| Unprocessed | | 15.52 | 14.99 | 2.33 | — | 2.63 ± 0.12 |
| 1000 | Nitrogen | 15.53 | 14.91 | 2.32 | 0.5 | 2.52 ± 0.13 |
| 900 | Methane | 14.31 | 14.77 | 2.11 | 11.6 | 2.39 ± 0.11 |
| 1000 | Methane | 9.89 | 18.94 | 1.87 | 32.5 | 1.86 ± 0.17 |
| 1100 | Methane | 7.27 | 23.2 | 1.69 | 51.4 | 1.51 ± 0.06 |

*% increase in carbon calculated on a constant silicon basis

Elemental analysis was determined by first determining the mass percentage of carbon using the ashing method specified in ASTM D1506, assuming all non-ash content was carbon. Inorganic elements were quantified by scanning electron microscopy/energy dispersive x-ray spectroscopy (SEM/EDS) of a thick layer of the ash stamped on an SEM stub with carbon tape. Regions measuring 560 microns×420 microns were scanned with an EDS detector until a total of 50,000,000 x-ray counts was registered.

The results demonstrate that carbon was deposited on the surface of the rC particles. The decrease in ash also suggests that ZnO in the rC was reduced and then the metallic zinc (boiling point 907° C.) evaporated. Assuming little or no loss of silicon during deposition, the increase in Si concentration in the ash suggests a reduced amount of ash, while the decreased proportion of Si in the rC suggests the addition of new carbon to the rC increasing with the processing temperature. Moreover, the decrease in I_{D}/I_{G} indicates that the crystallinity of the deposited carbon is increasing with the processing temperature.

Example 2—Reclaimed carbon (e.g., from CBP Cyprus Ltd) is coated with carbon in a pilot-scale fluidized bed reaction system substantially similar to the one discussed with respect to FIG. 2 of U.S. Pat. No. 10,087,330, the entire contents of which are incorporated by reference herein. The ideal fluidization velocity of the reclaimed carbon is evaluated with air at room temperature in a bench-scale fluidization device. The initial charge of reclaimed carbon starting material is loaded into the fluidized bed so that it sits on top of the bottom plate. The bed is then sealed and a flow of nitrogen was passed through the reclaimed carbon, entering through the bottom plenum, passing through the bottom plate and then the reclaimed carbon, and then finally exiting through the top of the fluidized bed reactor. Electrical heaters were activated to bring the bed temperature up to 1000° C. The nitrogen flow is then stopped and a natural gas stream with a superficial velocity roughly equal to the ideal fluidization velocity is turned on and the run initiated. Samples are pulled regularly from the bed using a dip pipe and measured to track the progress of the carbon black deposition. At the end of the desired run time, the natural gas flow is switched off along with the electrical heaters, and nitrogen is again passed to the fluidized bed while it cools down to room temperature. The final bed product is then collected from the bottom of the fluidized bed reactor. It is expected that this product will have carbon deposited on the surface and a reduced amount of zinc in comparison to the starting product.

Example 3—Particulate silica (e.g., precipitated silica) is coated with carbon in a pilot-scale fluidized bed reaction system with a similar configuration to the one discussed with respect to FIG. 2 of U.S. Pat. No. 10,087,330, the entire contents of which are incorporated by reference herein. The ideal fluidization velocity of the particulate silica is evaluated with air at room temperature in a bench-scale fluidization device. The initial charge of particulate silica starting material is loaded into the fluidized bed so that it sits on top of the bottom plate. The bed is then sealed and a flow of nitrogen was passed through the particulate silica, entering through the bottom plenum, passing through the bottom plate and then the particulate silica, and then finally exiting through the top of the fluidized bed reactor. Electrical heaters were activated to bring the bed temperature up to 1250° C. The nitrogen flow is then stopped and a natural gas stream with a superficial velocity roughly equal to the ideal fluidization velocity is turned on and the run initiated. Samples are pulled regularly from the bed using a dip pipe and measured to track the progress of the carbon black deposition. At the end of the desired run time, the natural gas flow is switched off along with the electrical heaters, and nitrogen is again passed to the fluidized bed while it cools down to room temperature. The final bed product is then collected from the bottom of the fluidized bed reactor. It is expected that this product will have carbon deposited on the surface.

Example 4. Elastomer composites with a particulate loading of 50 phr is prepared with each of the five particles from Example 1, the amount of smalls and curatives given in Table 2, and Kralex SBR 1502 styrene butadiene rubber (Synthos). All compositions are mixed in a 439 mL Brabender Prep-mixer with two cam rotors in two stages as described in Table 3. Compounds are sheeted on a 2-roll mill operated at 50° C. and about 22 rpm, followed by six pass-throughs with a nip gap about 5 mm, with a rest time before next stage of mixing (or curing, after the last stage) of at least 3 hours. Curing is performed in a heated press (150° C., 2500 lbs), for 30 minutes. Compounds prepared with carbon coated rC are expected to exhibit superior mechanical performance (e.g., an improvement of at least 5% in one or more of tensile modulus at 100% strain, tensile modulus at 300% strain, elongation at break, tan delta (60 degC), tear strength, and fatigue life) in comparison to compounds prepared with rC that has not been carbon coated.

TABLE 2

| Component | phr |
|---|---|
| 6PPD^{a} | 3 |
| TMQ^{b} | 1.5 |
| Zinc Oxide^{c} | 3 |
| Stearic Acid^{c} | 2 |
| Wax beads^{d} | 1 |
| BBTS^{e} | 1.5 |
| Sulfur^{c} | 1.5 |

^{a}N-(1,3-Dimethylbutyl)-N′-phenyl-p-phenylenediamine, 6PPD (Western Reserve Chemical)
^{b}poly(1,2-dihydro-2,2,4-trimethyl-quinoline), Antioxidant DQ pellets (Akrochem Corporation)
^{c}From Akrochem Corporation
^{d}AKROWAX ™ 5031 (Akrochem Corporation)
^{e}N-tert-butyl-2 benzothiazole sulfenamide (Akrochem Corporation)

TABLE 3
Stage 1

| Fill Factor, % | 70 |
|---|---|
| Rotor Speed, rpm | 80 |
| Start Temperature, ° C. | 85 |
| Time (s) | Description |
| 0 | Add polymer |
| 60-120 | Add filler gradually |
| — | Reduce speed to 60 degC. if temperature |
| | approaches 160 degC. |
| 180 | Scrape/Sweep, add smalls pre-blended |
| | (ZnO, Stearic Acid, Wax, 6PPD, TMQ) |
| 240 | Scrape/Sweep, adjust RPM to keep |
| | temperature <= 160 degC. |
| 300 | Dump |

Stage 2

| Fill Factor, % | 68 |
|---|---|
| Rotor Speed, rpm | 60 |
| Start Temperature, ° C. | 52 |
| Time (s) | Description |
| 0 | Add Stage 1 batch and curatives |
| 30 | Scrape/Sweep |
| 90 | Dump - Adjust rotor speed to |
| | not exceed 115° C. |

The present invention can include any combination of these various features or embodiments above and/or below as set forth in any sentences and/or paragraphs herein. Any combination of disclosed features herein is considered part of the present invention and no limitation is intended with respect to combinable features.

The applicant specifically incorporates the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A method to form carbon coated base particles, said method comprising introducing base particles into a chamber and subjecting the base particles to an energy source that is at least one of hot gas, microwave energy, induction energy, direct current passing through said base particles, electromagnetic radiation, or solar radiation, so as to form heated base particles, and feeding a hydrocarbon source that comprises a gas or vapor into said chamber, wherein the hydrocarbon source pyrolyzes, in at least in part, in said chamber to form carbon deposits, and thereby coating said heated base particles with said carbon deposits and form said carbon coated base particles, wherein the base particles optionally comprise reclaimed carbon particles.

2. The method of claim 1, wherein the base particles comprise one or more of A) carbon particles or particles that have at least 10% or at least 75% carbon content, B) carbon particles that are non-ASTM reinforcement grade particles, solid hydrothermal carbon (HTC), silicon-treated carbon black, silica coated carbon black, graphene, reduced graphene oxide, single walled carbon nanotubes, multi walled carbon nanotubes, carbon nanostructures, carbon black coated particles, biochar, and any combination of these, C) graphene oxide, lignin, nanocrystalline cellulose, bio-based particles, polysaccharides, engineered polysaccharides, or any combination of these, or D) precipitated silica, rice husk silica, clays, nanoclays, diatomaceous earth, metal oxides, metal carbonates, or any combination of these.

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. The method of claim 1, wherein the chamber comprises a fluidized bed reactor, an ablative pyrolysis reactor, a vacuum pyrolysis reactor, a fixed bed drop-type reactor, or a solar pyrolyzer.

15. (canceled)

16. (canceled)

17. (canceled)

18. (canceled)

19. The method of claim 1, wherein the method is conducted in the absence of a catalyst.

20. (canceled)

21. The method of claim 1, wherein the method yields at most 0.5 kg carbon dioxide and carbon monoxide/kg carbon coated particles.

22. (canceled)

23. (canceled)

24. (canceled)

25. (canceled)

26. (canceled)

27. The method of claim 1, wherein the base particles are on a fixed bed within the chamber or a moving bed that passes through the chamber.

28. (canceled)

29. (canceled)

30. (canceled)

31. (canceled)

32. (canceled)

33. (canceled)

34. The method of claim 1, wherein the chamber comprises at least a first chamber and a second chamber, wherein in the first chamber, the base particles are subjected to the microwave energy or induction energy such that the base particles reach an average surface temperature of at least 800 deg C. in the absence of any hydrocarbon source to obtain heated base particles, and then transporting said heated base particles to the second chamber where said feeding of the hydrocarbon source occurs.

35. (canceled)

36. (canceled)

37. (canceled)

38. The method of claim 34, wherein the first chamber is at least 25% smaller in volume compared to a volume of the second chamber.

39. (canceled)

40. The method of claim 1, wherein recycled iron or limestone is applied to at least a portion of the surface of the base particles prior to being subjected to said energy source.

41. (canceled)

42. (canceled)

43. The method of claim 1, further comprising conducting steam oxidation of the base particles in said chamber.

44. The method of claim 1, further comprising heating said carbon coated particles in a second step, in either the same chamber or a different chamber, in a neutral atmosphere or a reducing atmosphere.

45. The method of claim 1, wherein a non-reacting carrier gas is present with the hydrocarbon source.

46. (canceled)

47. (canceled)

48. The method of claim 1, further comprising introducing the carbon coated base particles into an additional chamber and subjecting the base particles to an energy source that is at least one of hot gas, microwave energy, induction energy, direct current passing through said base particles, electromagnetic radiation, or solar radiation, so as to form heated carbon coated base particles, and feeding a hydrocarbon source that comprises a gas or vapor into said additional chamber, wherein the hydrocarbon source pyrolyzes, in at least in part, in said additional chamber to form carbon deposits, and thereby coating said heated carbon coated base particles with additional carbon deposits.

49. A method to form carbon coated precipitated silica particles, said method comprising:
introducing precipitated silica particles into a chamber and subjecting the precipitated silica particles to microwave energy or induction energy to form heated precipitated silica particles, and feeding a hydrocarbon source that comprises a gas or vapor into said chamber, wherein the hydrocarbon source pyrolyzes, in at least in part, in said chamber to form carbon deposits, and thereby coating said heated precipitated silica particles with said carbon deposits and form said carbon coated precipitated silica particles.

50. A method of producing hydrogen, comprising performing the method of any of the preceding claims, wherein pyrolysis of the hydrocarbon source results in the production of a gas stream comprising hydrogen.

51. (canceled)

52. (canceled)

53. (canceled)

54. Carbon coated particles each comprising a base particle and carbon deposits disposed about the external surface of the base particle, the carbon coated particles having a ratio of the areas of the Raman D band (1340 cm⁻¹) and the Raman G band (1590 cm⁻¹) of 0.5 to 2.45, for example, from 1 to 2.45 or from 1.5 to 2.45.

55. The carbon coated particles of claim 54, wherein the base particles comprise one or more of A) carbon particles or particles that have at least 10 wt % or at least 75 wt % carbon content, B) carbon particles that are non-ASTM reinforcement grade particles, solid hydrothermal carbon (HTC), silicon-treated carbon black, silica coated carbon black, graphene, reduced graphene oxide, single walled carbon nanotubes, multi walled carbon nanotubes, carbon nanostructures, carbon black coated particles, biochar, and any combination of these, C) graphene oxide, lignin, nanocrystalline cellulose, bio-based particles, polysaccharides, engineered polysaccharides, or any combination of these, or D) precipitated silica, rice husk silica, clays, nanoclays, diatomaceous earth, metal oxides, metal carbonates, or any combination of these.

56. (canceled)

57. (canceled)

58. (canceled)

59. (canceled)

60. (canceled)

61. (canceled)

62. A rubber article incorporating the carbon coated particles of claim 54.

63. The rubber article of claim 62, wherein the rubber article is a tire component selected from the group consisting of tire tread, sub-tread, wire skim, side wall, and cushion gum, an engine mount, a hydro-mount, a bridge bearing, a seismic isolator, a tank track, a tank tread, a mining belt, a hose, a gasket, a seal, a blade, a weather stripping article, a bumper or an anti-vibration part.

64. Elastomer composite comprising the carbon coated particles of claim 54, wherein the base particle is reclaimed carbon, the elastomer composite having at least one mechanical property selected from tensile modulus at 100% strain, tensile modulus at 300% strain, elongation at break, tan delta at 60 degC, tear strength, and fatigue life with a magnitude at least 5% greater than that of an elastomer composite having the same composition but with reclaimed carbon instead of carbon coated particles.
